(19) United States
(12) Patent Application Publication
(10) Pub. No.: US 2025/0253128 A1
(43) Pub. Date: Aug. 7, 2025

(54) SUBSTRATE PROCESSING APPARATUS AND SUBSTRATE PROCESSING METHOD USING THE SAME

(71) Applicant: Samsung Electronics Co., Ltd., Suwon-si (KR)

(72) Inventors: Daehyun LEE, Suwon-si (KR); TAEIL CHO, Suwon-si (KR); Huitae KANG, Suwon-si (KR); KYUNG-SUN KIM, Suwon-si (KR); Juho Kim, Suwon-si (KR); DONGHYEON NA, Suwon-si (KR); NAOHIKO OKUNISHI, Suwon-si (KR); KUIHYUN YOON, Suwon-si (KR); SEUNGBIN LIM, Suwon-si (KR)

(21) Appl. No.: 18/815,184

(22) Filed: Aug. 26, 2024

(30) Foreign Application Priority Data
Feb. 2, 2024 (KR) 10-2024-0016530

(51) Int. Cl. H01J 37/32

(52) U.S. Cl. CPC H01J 37/3211; H01J 37/32119

(57) ABSTRACT

A substrate processing apparatus is disclosed. The substrate processing apparatus may include a process chamber and a plasma generating portion on the process chamber. The plasma generating portion may include an inner antenna ring, an outer antenna ring surrounding the inner antenna ring, and a core ring between the inner antenna ring and the outer antenna ring. The core ring may include a magnetic material.

### CROSS-REFERENCE TO RELATED APPLICATIONS

This U.S. non-provisional patent application claims priority under 35 U.S.C. § 119 to Korean Patent Application No. 10-2024-0016530, filed on Feb. 2, 2024, in the Korean Intellectual Property Office, the entire contents of which are hereby incorporated by reference.

### BACKGROUND OF THE INVENTION

The present disclosure relates to a substrate processing apparatus and a substrate processing method using the same, and in particular, to a substrate processing apparatus, which is configured to improve uniformity of plasma, and a substrate processing method using the same.

A semiconductor device is fabricated through various processes. For example, the semiconductor device is fabricated by performing a photolithography process, an etching process, and a deposition process on a wafer. Various fluidic materials are used in these processes. Plasma may be used in an etching process and/or a deposition process. An electrode is used to produce and/or control the plasma, during the process.

### SUMMARY

An embodiment of the inventive concept provides a substrate processing apparatus, which is configured to improve uniformity of plasma, and a substrate processing method using the same.

An embodiment of the inventive concept provides a substrate processing apparatus, which is configured to uniformly perform a fabrication process on a substrate, and a substrate processing method using the same.

According to an embodiment of the inventive concept, a substrate processing apparatus may include a process chamber and a plasma generating portion on the process chamber. The plasma generating portion may include an inner antenna ring, a first outer antenna ring surrounding the inner antenna ring, and a core ring between the inner antenna ring and the first outer antenna ring. The core ring may include a magnetic material.

According to an embodiment of the inventive concept, a substrate processing apparatus may include a stage including a cooling plate and a chuck, a plasma window on the stage, antenna rings on the plasma window, a gas supplying device connected to the plasma window, and an RF power generator electrically connected to the antenna rings. The antenna rings may include an inner antenna ring and first to third outer antenna rings outside the inner antenna ring. A core ring may be placed between the inner antenna ring and the first outer antenna ring and may include a magnetic material.

According to an embodiment of the inventive concept, a substrate processing method may include preparing a substrate in a substrate processing apparatus, generating plasma on the substrate using a plasma generating portion, and processing the substrate using the plasma. The plasma generating portion may include an inner antenna ring, a first outer antenna ring outside the inner antenna ring, and a core ring between the inner antenna ring and the first outer antenna ring. The generating of the plasma may include changing a position of the core ring.

### BRIEF DESCRIPTION OF THE DRAWINGS

FIG. 1 is a sectional view illustrating a substrate processing apparatus according to an embodiment of the inventive concept.

FIG. 2 is an enlarged sectional view illustrating a portion (e.g., P1 of FIG. 1) of a stage according to an embodiment of the inventive concept.

FIG. 3 is an enlarged sectional view illustrating a portion (e.g., P2 of FIG. 1) of a plasma generating portion according to an embodiment of the inventive concept.

FIG. 4 is a perspective view illustrating a plasma generating portion according to an embodiment of the inventive concept.

FIG. 5 is a plan view illustrating a plasma generating portion according to an embodiment of the inventive concept.

FIG. 6 is a flow chart illustrating a substrate processing method according to an embodiment of the inventive concept.

FIGS. 7 to 10C are diagrams illustrating a substrate processing method according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus duplicated descriptions the like elements may be omitted.

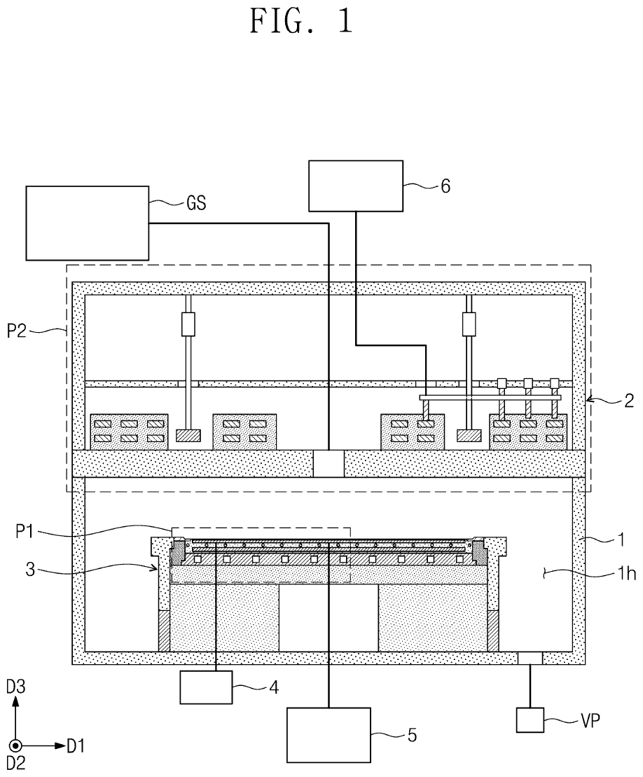

FIG. 1 is a sectional view illustrating a substrate processing apparatus according to an embodiment of the inventive concept.

In the present specification, a first direction D1 and a second direction D2 may not be parallel to each other. A third direction D3 may not be parallel to the first direction D1 and the second direction D2. Each of the first and second directions D1 and D2 may be a horizontal direction. The third direction D3 may be a vertical direction. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Referring to FIG. 1, a substrate processing apparatus may be provided. The substrate processing apparatus may be configured to perform a fabrication process on a substrate. In the present specification, the term ‘substrate’ may mean a silicon wafer, but the inventive concept is not limited to this example. For example, the substrate processing apparatus may be configured to perform an etching process on the substrate. For this, the substrate processing apparatus may be configured to generate plasma. For example, the substrate processing apparatus may be configured to generate the plasma using an induced current. For example, the substrate processing apparatus may be an inductively coupled plasma (ICP) apparatus.

The substrate processing apparatus may include a process chamber 1, a plasma generating portion 2, a stage 3, a DC power generator 4, a first RF power generator 5, a second RF power generator 6, a gas supplying device GS, and a vacuum pump VP.

The process chamber 1 may be configured to have a process space 1h. The process space 1h may be used to perform a fabrication process on a substrate. During the process on the substrate, the process space 1h may be in a substantially vacuum state. For example, the vacuum state of the process space 1h during the process on the substrate may be at a pressure lower than the atmospheric pressure. For example, the pressure may be lower than 100 Pa or lower than 0.1 Pa in certain embodiments. For example, the process space 1h may be separated and isolated from the external space (e.g., the outside of the chamber 1). The process chamber 1 may have the shape of a circular cylinder, but the inventive concept is not limited to this example.

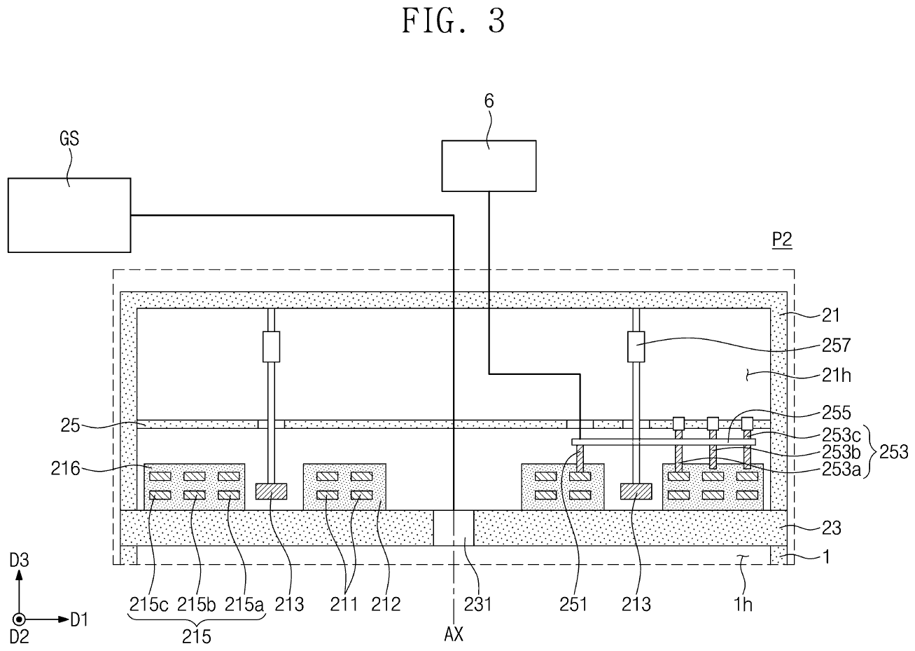

The plasma generating portion 2 may be placed on the process chamber 1. The plasma generating portion 2 may be configured to generate plasma. For example, when an RF power is applied to the plasma generating portion 2, the plasma may be formed from a portion of a gas in the process space 1h. The plasma generating portion 2 will be described in more detail with reference to FIGS. 3 to 5.

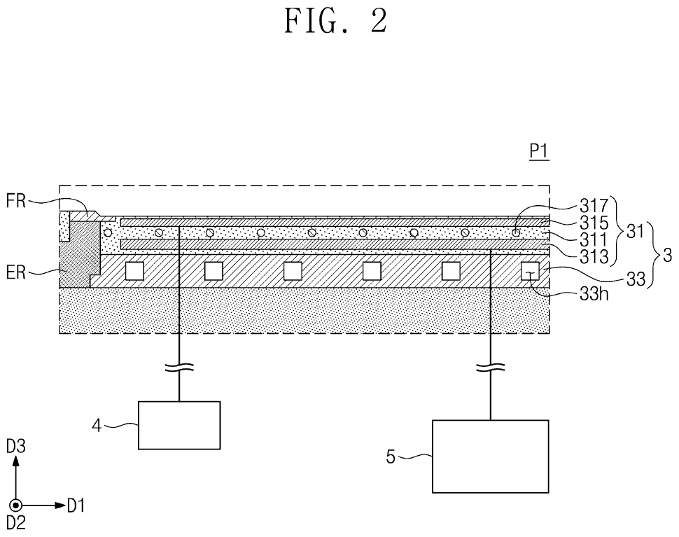

The stage 3 may be disposed in the process chamber 1. For example, the stage 3 may be placed in the process space 1h. The stage 3 may be used to support and/or fasten the substrate. A fabrication process on the substrate may be performed when the substrate is loaded on the stage 3. The stage 3 will be described in more detail with reference to FIG. 2.

The DC power generator 4 may be electrically connected to the stage 3. As used herein, components described as being “electrically connected” are configured such that an electrical signal can be transferred from one component to the other (although such electrical signal may be attenuated in strength as it is transferred and may be selectively transferred). The DC power generator 4 may be placed outside the process chamber 1, but the inventive concept is not limited to this example. A DC power may be applied to the stage 3. The substrate may be fastened onto the stage 3 by the DC power that is applied from the DC power generator 4.

The first RF power generator 5 may be electrically connected to the stage 3. The first RF power generator 5 may be placed outside the process chamber 1, but the inventive concept is not limited to this example. The first RF power generator 5 may be configured to supply the RF power onto the stage 3. Thus, the plasma in the process space 1h may be controlled.

The second RF power generator 6 may be electrically connected to the plasma generating portion 2. The second RF power generator 6 may be placed outside the plasma generating portion 2, but the inventive concept is not limited to this example. The second RF power generator 6 may be configured to supply an RF power to the plasma generating portion 2. Thus, plasma may be generated on the stage 3, in the process space 1h.

The gas supplying device GS may be configured to supply a gas into the process space 1h. The gas supplying device GS may include, for example, a gas tank, a compressor, and a valve. Plasma may be generated from a portion of the gas, which is supplied into the process space 1h from the gas supplying device GS.

The vacuum pump VP may be connected to the process space 1h. The vacuum pump VP may be used to remove the gas from the process space 1h. Thus, the process space 1h may be maintained to a vacuum pressure state (e.g., a vacuum state). For example, the vacuum pump VP may include a turbomolecular pump (TMP).

FIG. 2 is an enlarged sectional view illustrating a portion (e.g., P1 of FIG. 1) of a stage according to an embodiment of the inventive concept.

Referring to FIG. 2, the stage 3 may include a cooling plate 33 and a chuck 31 on the cooling plate 33.

A substrate may be disposed on the chuck 31. The chuck 31 may be used to fasten the substrate. The chuck 31 may include a chuck body 311, a plasma electrode 313, a chuck electrode 315, and a heater 317.

The chuck body 311 may have the shape of a circular cylinder (e.g., a cylindrical shape). The substrate disposed on the chuck 31 may be in contact with a top surface of the chuck body 311. A focus ring FR and an edge ring ER may be provided to enclose the chuck body 311. The chuck body 311 may include, for example, a ceramic material, but the inventive concept is not limited to this example. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The plasma electrode 313 may be placed in the chuck body 311. For example, the plasma electrode 313 may be enclosed/surrounded by the chuck body 311. The plasma electrode 313 may have the shape of a circular plate, e.g., may be a circular conductor plate, but the inventive concept is not limited to this example. An RF power may be applied to the plasma electrode 313. For example, the first RF power generator 5 may be configured to apply the RF power to the plasma electrode 313. The RF power applied to the plasma electrode 313 may be used to control the plasma in the process space 1h of FIG. 1. The plasma electrode 313 may be formed of or include, for example, aluminum (Al) or the like.

The chuck electrode 315 may be placed in the chuck body 311. For example, the chuck electrode 315 may be enclosed/surrounded by the chuck body 311. The chuck electrode 315 may be located on/above the plasma electrode 313. A DC power may be applied to the chuck electrode 315. For example, the DC power generator 4 may be configured to apply a DC power to the chuck electrode 315. The DC power applied to the chuck electrode 315 may be used to fasten the substrate on the chuck body 311. The chuck electrode 315 may be formed of or include, for example, aluminum (Al), but the inventive concept is not limited to this example.

The heater 317 may be placed in the chuck body 311. For example, the heater 317 may be enclosed/surrounded by the chuck body 311. The heater 317 may be placed between the chuck electrode 315 and the plasma electrode 313. The heater 317 may be configured to emit heat. In this case, the temperatures of the chuck body 311 and neighboring elements may be increased, and the temperature of the substrate on the chuck body 311 may be controlled. The heater 317 may include, for example, a heating line. In an embodiment, the heater 317 may include a plurality of heating lines, which are disposed to be concentric with each other, when viewed in a plan view.

The cooling plate 33 may be placed below the chuck 31. The cooling plate 33 may have a cooling hole 33h. Coolant may be provided to flow through the cooling hole 33h. The coolant in the cooling hole 33h may be used to absorb heat. In this case, the temperatures of the cooling plate 33 and neighboring elements, e.g., the chuck 31 including the chuck body 311, may be lowered, and the temperature of the substrate on the chuck body 311 may be controlled.

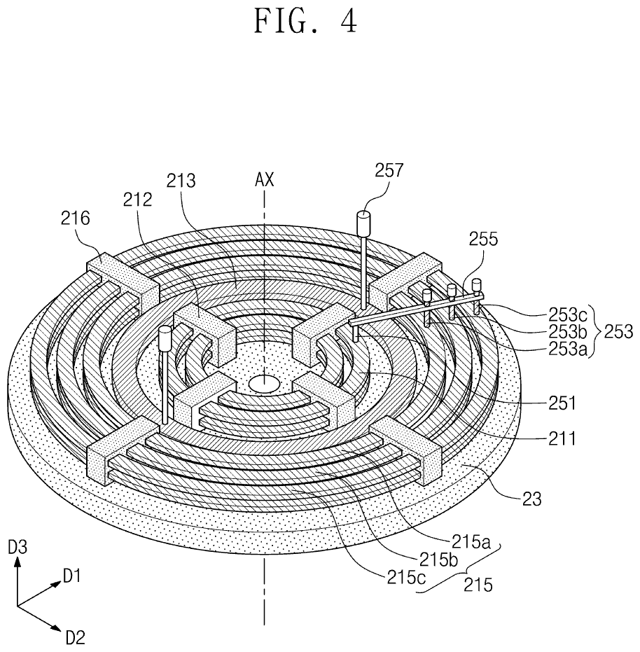

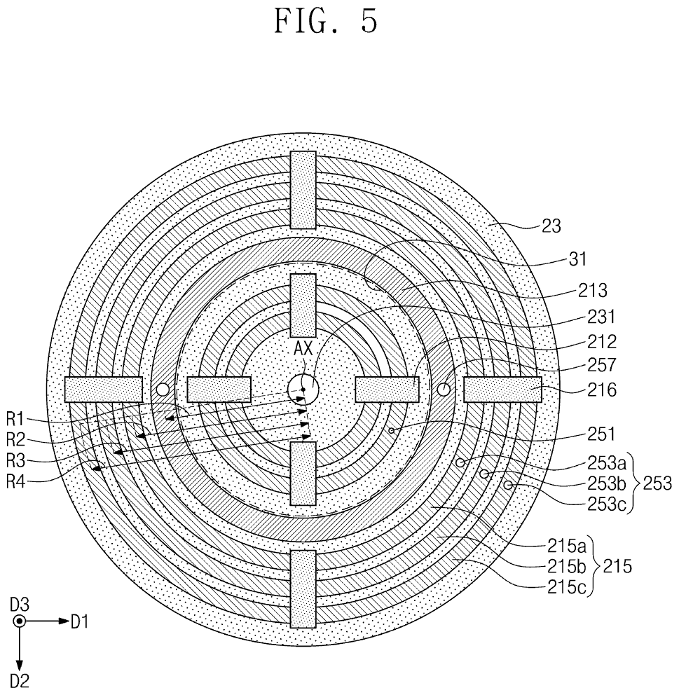

FIG. 3 is an enlarged sectional view illustrating a portion (e.g., P2 of FIG. 1) of a substrate processing apparatus including a plasma generating portion 2 according to an embodiment of the inventive concept. FIG. 4 is a perspective view illustrating a plasma generating portion 2 according to an embodiment of the inventive concept. FIG. 5 is a plan view illustrating a plasma generating portion 2 according to an embodiment of the inventive concept.

Referring to FIGS. 3, 4, and 5, the plasma generating portion 2 may include a coil chamber 21, a plasma window 23, a separation plate 25, an inner antenna ring 211, a core ring 213, an outer antenna ring 215, an inner rod 251, and an outer rod 253.

The coil chamber 21 may be placed on the process chamber 1. The coil chamber 21 may be configured to have an upper space 21h. The upper space 21h may be placed on the process space 1h. The upper space 21h may be maintained to an atmospheric pressure state, unlike the process space 1h. The separation plate 25, the inner antenna ring 211, the core ring 213, and the outer antenna ring 215 may be disposed in the upper space 21h of the coil chamber 21.

The plasma window 23 may be placed between the process chamber 1 and the coil chamber 21. The plasma window 23 may separate the process space 1h of the process chamber 1 from the upper space 21h of the coil chamber 21. For example, the plasma window 23 may include a ceramic material.

An injector 231 may be provided in the plasma window 23. The injector 231 may be located on a center axis AX. The center axis AX may be an axis passing through the centers of the inner antenna ring 211, the core ring 213, and the outer antenna ring 215, e.g., in a vertical direction. For example, the center axis AX may pass through the injector 231. For example, the center axis AX may be parallel to the third direction D3. The injector 231 may be connected to the gas supplying device GS. The injector 231 may provide a plurality of holes. Thus, the gas, which is provided from the gas supplying device GS, may be uniformly supplied into the process space 1h.

The inner antenna ring 211 may be placed between the plasma window 23 and the separation plate 25, in the coil chamber 21. The inner antenna ring 211 may be a rotating object (e.g., a solid of revolution) whose center is located on the center axis AX. For example, the center axis AX may be the axis of revolution. When viewed in a plan view, the inner antenna ring 211 may have a ring shape. For example, the inner antenna ring 211 may have the shape of a plurality of concentric circles/rings as shown in FIGS. 4 and 5. The plurality of concentric circles/rings may be spaced apart from each other in the first direction D1 (e.g., in a radial direction) and/or the third direction D3. The plurality of concentric circles/rings may be connected to each other, but the inventive concept is not limited to this example. FIGS. 3 and 4 show that a plurality of rings are spaced apart from each other in a radial direction and/or in a vertical direction in a region where the inner antenna ring 211 is placed. The plurality of rings of conductors electrically connected to each other may form the inner antenna ring 211 in certain embodiments. For example, the inner antenna ring 211 may have a coil shape. In some embodiments, the plasma generating portion 2 may include a plurality of inner antenna rings 211, and the plurality of inner antenna rings 211 may be electrically connected to each other. In certain embodiments, the plurality of inner antenna rings 211 may be electrically isolated/insulated from each other. The inner antenna ring 211 may include a metallic material. For example, the inner antenna ring 211 may be formed of or include copper (Cu) and/or silver (Ag). For example, the inner antenna ring 211 may include a copper pattern/ring plated with silver (Ag).

First insulating members 212 may be provided to enclose a portion of the inner antenna ring 211. The first insulating members 212 may be in contact with the plasma window 23 and may be spaced apart from the separation plate 25, e.g., in a vertical direction, but the inventive concept is not limited to this example. The first insulating members 212 may be in contact with the inner antenna ring 211 and may support the inner antenna ring 211. The first insulating members 212 may be spaced apart from the core ring 213, e.g., in a radial direction. When viewed in a plan view, the first insulating members 212 may be spaced apart from each other. For example, the first insulating members 212 may be spaced apart from each other in a circumferential direction or around the center axis AX. Four first insulating members 212 are illustrated in the drawings, but the inventive concept is not limited to this example. In an embodiment, the number of the first insulating members 212 may be variously changed. The first insulating members 212 may include an insulating material. For example, the first insulating members 212 may include a plastic material. For example, the first insulating members 212 may be formed of or include polyether ether ketone (PEEK).

The outer antenna ring 215 may be placed outside the inner antenna ring 211, in the coil chamber 21. When viewed in a plan view, the outer antenna ring 215 may be provided to enclose the inner antenna ring 211. The outer antenna ring 215 may be spaced apart from the inner antenna ring 211 in an outward direction, e.g., in the radial direction. For example, the outer antenna ring 215 and the inner antenna ring 211 may not be in contact with each other. The outer antenna ring 215 may be a rotating object that has the same center axis AX as that of the inner antenna ring 211. For example, the outer antenna ring 215 may have a shape of a solid of revolution and the center axis AX may be the axis of revolution of the outer antenna ring 215. The outer antenna ring 215 may include a metallic material. The outer antenna ring 215 may be formed of or include, for example, copper (Cu) and/or silver (Ag). For example, the outer antenna ring 215 may include a copper pattern/ring plated with silver (Ag).

In an embodiment, a plurality of outer antenna rings 215 may be provided. In this case, the plurality of outer antenna rings 215 may include a first outer antenna ring 215a, a second outer antenna ring 215b, and a third outer antenna ring 215c. The second outer antenna ring 215b may be placed outside the first outer antenna ring 215a, e.g., in a radial direction, and the third outer antenna ring 215c may be placed outside the second outer antenna ring 215b, e.g., in the radial direction. For example, the second outer antenna ring 215b may surround the first outer antenna ring 215a, and the third outer antenna ring 215c may surround the second outer antenna ring 215b, e.g., in a plan view. When viewed in a plan view, the second outer antenna ring 215b may be placed between the first outer antenna ring 215a and the third outer antenna ring 215c. The first to third outer antenna rings 215a, 215b, and 215c may be spaced apart from each other in a horizontal direction or in a radial direction. FIGS. 3 and 4 show that each of the first to third outer antenna rings 215a, 215b and 215c includes two rings spaced apart from each other in a vertical direction. The two rings of each of the first to third outer antenna rings 215a, 215b and 215c may be conductor rings electrically connected to each other. For example, each of the first to third outer antenna rings 215a, 215b and 215c may include a plurality of rings spaced apart from each other in a vertical direction and/or in a radial direction and electrically connected to each other in certain embodiments. For example, each of the first to third outer antenna rings 215a, 215b and 215c may have a coil shape. In certain embodiments, the plurality of rings of each of the first to third outer antenna rings 215a, 215b and 215c may be electrically isolated/insulated from each other.

Second insulating members 216 may be provided to enclose a portion of the outer antenna rings 215. The second insulating members 216 may be in contact with the plasma window 23 and may be spaced apart from the separation plate 25, e.g., in a vertical direction, but the inventive concept is not limited to this example. The second insulating members 216 may be in contact with the outer antenna rings 215 and may support the outer antenna rings 215. For example, the second insulating members 216 may be provided to enclose a portion of each of the first to third outer antenna rings 215a, 215b, and 215c. The second insulating members 216 may be spaced apart from the core ring 213. For example, the core ring 213 may be placed between the first insulating members 212 and the second insulating members 216, which are adjacent to each other. When viewed in a plan view, the second insulating members 216 may be spaced apart from each other. For example, the second insulating members 216 may be spaced apart from each other in a circumferential direction or around the center axis AX. Four second insulating members 216 are illustrated in the drawings, but the inventive concept is not limited to this example. In an embodiment, the number of the second insulating members 216 may be variously changed. For example, the second insulating members 216 may include the same material as the first insulating members 212.

When viewed in a plan view, the core ring 213 may be placed between the inner and outer antenna rings 211 and 215. For example, the core ring 213 may be placed outside the inner antenna ring 211 and inside the outer antenna rings 215. The core ring 213 may not be in contact with the inner and outer antenna rings 211 and 215. The core ring 213 may be a rotating object having the same center axis AX as the inner and outer antenna rings 211 and 215. For example, the core ring 213 may have a shape of a solid of revolution, and the center axis AX may be the axis of revolution of the core ring 213. When viewed in a plan view, the core ring 213 may have a ring shape. For example, the core ring 213 may be formed of or include a magnetic material. The permeability of the magnetic material may be about 200,000 H/m, but the inventive concept is not limited to this example. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Actuators 257 may be provided on the core ring 213. The actuators 257 may be connected to the coil chamber 21. The actuators 257 may connect the core ring 213 to the coil chamber 21. Each of the actuators 257 may extend lengthwise in the third direction D3 to penetrate a portion of the separation plate 25. The actuators 257 may be configured to move the core ring 213 in a vertical direction (e.g., the third direction D3). For example, the actuators 257 may be used to control a height or level of the core ring 213. The actuators 257 may be disposed around the center axis AX to face each other. For example, the actuators 257 may be disposed at opposite sides of the upper space 21h with the center axis AX therebetween. Two actuators 257 are illustrated in the drawings, but the inventive concept is not limited to this example. In an embodiment, the number of the actuators 257 may be variously changed.

The inner rod 251 may be provided on the inner antenna ring 211. The inner rod 251 may be electrically connected to the second RF power generator 6. The inner rod 251 may be in contact with the inner antenna ring 211. For example, an RF power transferred from the second RF power generator 6 may be applied to the inner antenna ring 211 through the inner rod 251. The inner rod 251 may have a shape that extends lengthwise in third direction D3.

The outer rod 253 may be provided on the outer antenna ring 215. The plasma generating portion 2 may include a plurality outer rods 253. The outer rods 253 may be electrically connected to the second RF power generator 6. For example, the outer rods 253 may include a first rod 253a, a second rod 253b, and a third rod 253c. The first rod 253a may be placed on the first outer antenna ring 215a, the second rod 253b may be placed on the second outer antenna ring 215b, and the third rod 253c may be placed on the third outer antenna ring 215c. For example, each of the first to third rods 253a, 253b, and 253c may be electrically connected to a corresponding one of the first to third outer antenna rings 215a, 215b, and 215c. At least one of the first to third rods 253a, 253b, and 253c may be in contact with at least a corresponding one of the first to third outer antenna rings 215a, 215b, and 215c. The RF power of the second RF power generator 6 may be applied to at least one of the first to third outer antenna rings 215a, 215b, and 215c through the first to third rods 253a, 253b, and 253c. For example, the RF power may be selectively applied to at least one of the first to third outer antenna rings 215a, 215b, and 215c. Each of the first to third rods 253a, 253b, and 253c may have a shape that extends in the third direction D3.

A conductive supporter 255 may be provided to electrically connect the inner rod 251 to the outer rods 253. The conductive supporter 255 may be placed on the inner antenna ring 211, the core ring 213, and the outer antenna rings 215. The conductive supporter 255 may be electrically connected to the second RF power generator 6. For example, a power transferred from the second RF power generator 6 may be applied to the inner rod 251 and the outer rods 253 through the conductive supporter 255. The inner rod 251, the outer rods 253, and the conductive supporter 255 may constitute a rod assembly.

Since each of the inner antenna ring 211, the core ring 213, and the outer antenna rings 215 is a rotating object (e.g., a solid of revolution) whose center is located on the center axis AX, it may have a radius and a diameter. Here, the diameter may be 2 times the radius. The radius of each of the inner antenna ring 211, the core ring 213, and the outer antenna rings 215 may be a mean distance from the center axis AX to a corresponding one of the inner antenna ring 211, the core ring 213, and the outer antenna rings 215.

When viewed in a plan view, the core ring 213 may be larger than the inner antenna ring 211. For example, the core ring 213 may have a first radius R1. Here, the first radius R1 may range from about 150 mm to about 155 mm. For example, the diameter of the core ring 213 may range from about 300 mm to about 310 mm. When viewed in a plan view, a diameter of the core ring 213 may be equal to or larger than a diameter of the chuck 31 of the stage 3 of FIG. 1.

When viewed in a plan view, the outer antenna ring 215 may be larger than the core ring 213. For example, the first outer antenna ring 215a may have a second radius R2. The second outer antenna ring 215b may have a third radius R3. The third outer antenna ring 215c may have a fourth radius R4. Among the first to third outer antenna rings 215a, 215b, and 215c, the first outer antenna ring 215a may be the smallest, and the third outer antenna ring 215c may be the largest. For example, the fourth radius R4 may be larger than the third radius R3, and the third radius R3 may be larger than the second radius R2. The second radius R2 may be about 155 mm. The third radius R3 may be about 185 mm. The fourth radius R4 may be about 215 mm. For example, the diameter of the first outer antenna ring 215a may be about 310 mm, the diameter of the second outer antenna ring 215b may be about 370 mm, and the diameter of the third outer antenna ring 215c may be about 430 mm. However, the inventive concept is not limited to this example, and the second to fourth radii R2, R3, and R4 may be variously changed.

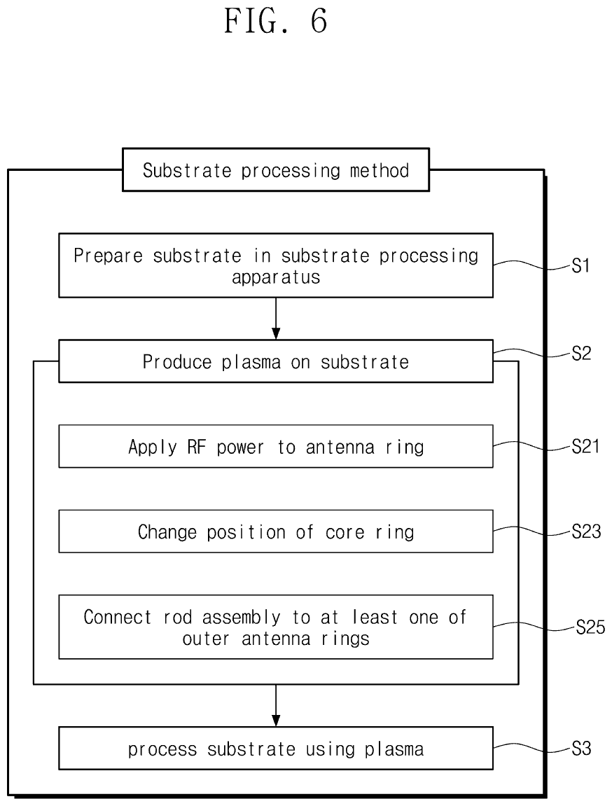

FIG. 6 is a flow chart illustrating a substrate processing method according to an embodiment of the inventive concept.

Referring to FIG. 6, a substrate processing method may be provided. The substrate processing method may be a method of processing a substrate using the substrate processing apparatus described with reference to FIGS. 1 to 5. The substrate processing method may include preparing/providing a substrate in (into) the substrate processing apparatus (in S1), producing plasma on the substrate (in S2), and processing the substrate using the plasma (in S3).

The producing of the plasma on the substrate (in S2) may include applying an RF power to an antenna ring (in S21), changing a position of the core ring (in S23), and connecting a rod assembly to at least one of outer antenna rings (in S25).

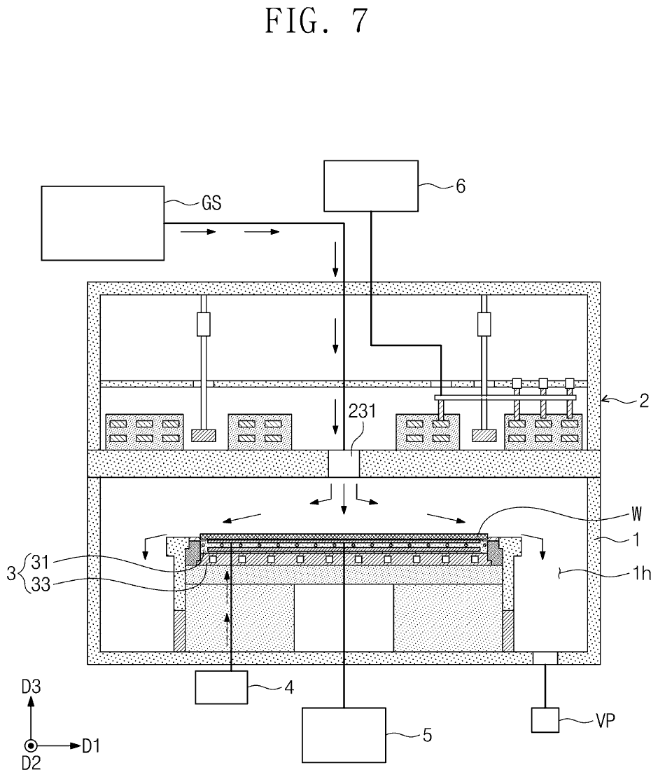

Hereinafter, the substrate processing method of FIG. 6 will be described in more detail with reference to FIGS. 7 to 10C.

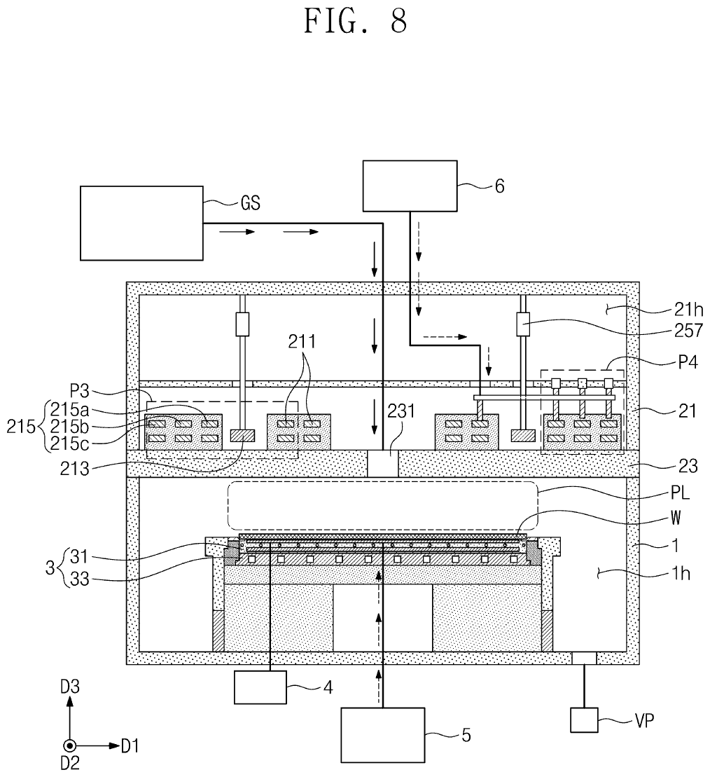

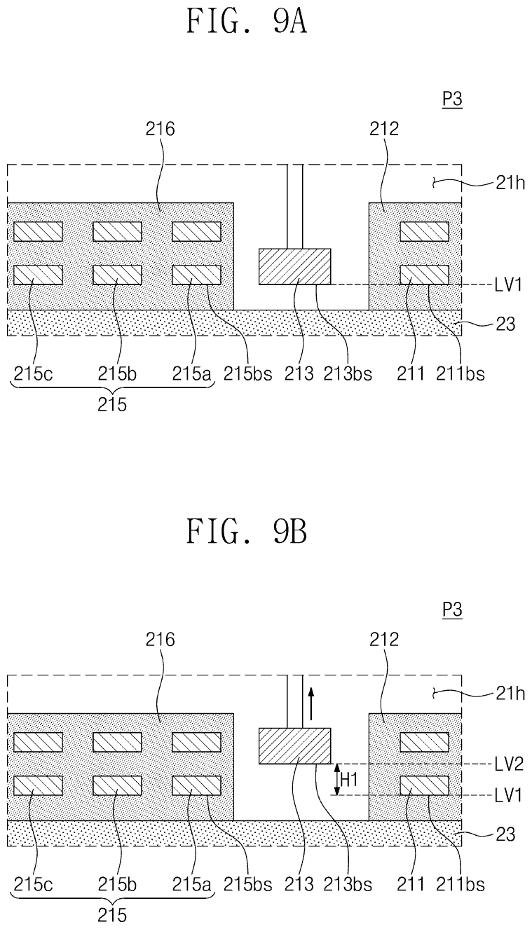

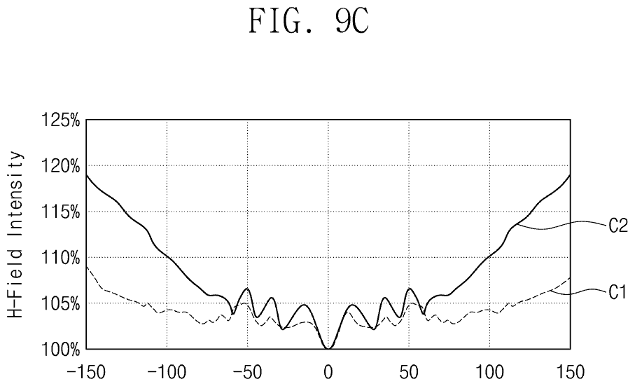

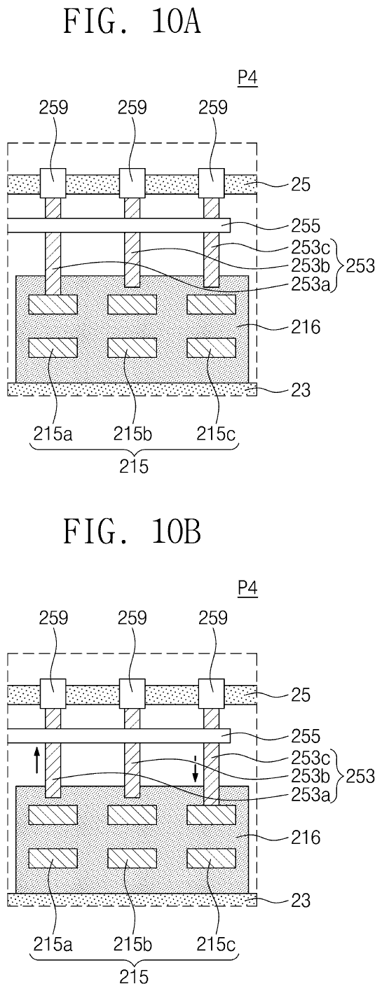

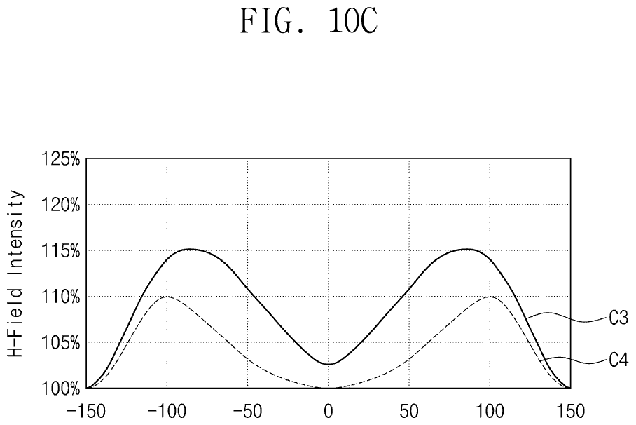

FIGS. 7 to 10C are diagrams illustrating a substrate processing method according to an embodiment of the inventive concept. FIGS. 7 and 8 are sectional views illustrating a substrate processing method according to an embodiment of the inventive concept. FIGS. 9A and 9B are enlarges sectional views illustrating a portion ‘P3’ of FIG. 8, and FIG. 9C is a graph showing a state of the substrate processing apparatus of FIGS. 9A and 9B. FIGS. 10A and 10B are enlarges sectional views illustrating a portion ‘P4’ of FIG. 8, and FIG. 10C is a graph showing a state of the substrate processing apparatus of FIGS. 10A and 10B.

Referring to FIGS. 6 and 7, the preparing of the substrate in the substrate processing apparatus (in S1) may include placing a substrate W on the chuck 31 of the stage 3, fastening the substrate W to the chuck 31 of the stage 3, and supplying a gas into the substrate processing apparatus.

The chuck 31 of the stage 3 may fasten the substrate W, after the placing of the substrate W on the chuck 31 of the stage 3. The fastening of the substrate W may be performed by the DC power generator 4. For example, the DC power, which is applied to the chuck 31 from/by the DC power generator 4, may be used to generate an electrostatic force between the substrate W and the chuck 31. Thus, the substrate W may be fastened onto the chuck 31.

The supplying of the gas in the substrate processing apparatus may be performed using the gas supplying device GS. The gas, which is supplied from the gas supplying device GS, may be supplied into the process space 1h through the injector 231. The gas, which is supplied into the process space 1h, may be exhausted to the outside through the vacuum pump VP, e.g., after a process using the gas is completed. In an embodiment, the gas, which is supplied in the preparing of the substrate (in S1), may include an inert gas (e.g., nitrogen (N₂) and/or argon (Ar)).

Referring to FIGS. 6 and 8, The producing of the plasma on the substrate (in S2) may include supplying a gas into the substrate processing apparatus, applying an RF power to an antenna ring (in S21), changing a position of the core ring (in S23), and connecting a rod assembly to at least one of outer antenna rings (in S25).

The supplying of the gas in the substrate processing apparatus may be performed using the gas supplying device GS. For example, the gas, which is supplied in the producing of the plasma (in S2), may include a reaction gas (e.g., chlorine (Cl₂), hydrofluoric acid (HF), and/or silicon tetrachloride (SiCl₄)).

The applying of the RF power to the antenna ring (in S21) may be performed by the second RF power generator 6. The RF power, which is generated by the second RF power generator 6, may be applied to the inner and outer antenna rings 211 and 215 through the rod assembly. In the step of applying the RF power to the antenna ring, the RF power may not be applied to the core ring 213. For example, the RF power may be applied to only the inner and outer antenna rings 211 and 215, and not be applied to the core ring 213. The RF power, which is applied to the inner and outer antenna rings 211 and 215, may be used to produce an electromagnetic field. The electromagnetic field may be used to generate plasma PL from a portion of the gas, which is supplied into the process space 1h, and here, the plasma PL may be generated between the stage 3 and the plasma window 23.

The processing of the substrate using the plasma (in S3) may include applying the RF power to the chuck 31 of the stage 3. The applying of the RF power to the chuck 31 may be performed by the first RF power generator 5. The RF power applied to the chuck 31 may pull particles in the plasma PL toward the substrate W. Thus, a portion of the substrate W may be removed by the particles in the plasma PL. For example, the process of the substrate (in S3) may include or may be etching a portion of the substrate W. For example, the substrate processing apparatus may be an etching apparatus, which is used to fabricate a semiconductor device.

Referring to FIGS. 6, 8, 9A, 9B, and 9C, the changing of the position of the core ring (in S23) may include changing the height or level of the core ring 213.

For example, a bottom surface 211bs of the inner antenna ring 211 and a bottom surface 215bs of the outer antenna ring 215 may be placed on the same plane. For example, the bottom surfaces of the first to third outer antenna rings 215a, 215b, and 215c may be placed on the same plane. For example, the inner and outer antenna rings 211 and 215 may be placed at substantially the same level/height, but the inventive concept is not limited to this example. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. In the present specification, the term ‘level’ may be a distance from the stage 3 in a vertical direction.

In an embodiment, a bottom surface 213bs of the core ring 213 may be placed on the same plane as the bottom surface 211bs of the inner antenna ring 211 and the bottom surface 215bs of the outer antenna ring 215. In this case, the bottom surface 213bs of the core ring 213 may be located at a first level LV1.

In an embodiment, the core ring 213 may be moved in a vertical direction by the actuators 257. The bottom surface 213bs of the core ring 213 may be placed at a level that is higher than the bottom surface 211bs of the inner antenna ring 211 and the bottom surface 215bs of the outer antenna ring 215. In this case, the bottom surface 213bs of the core ring 213 may be located at a second level LV2. The second level LV2 may be higher than the first level LV1, and a difference between the second level LV2 and the first level LV1 may be a first height H1. For example, the first height H1 may be about 50 mm or less.

In the graph of FIG. 9C, the horizontal axis may represent center and edge regions of the substrate W, e.g., positions along a horizontal line passing through the center of the substrate W from one edge of the substrate W to an opposite edge of the substrate W. For example, the position of 0 on the horizontal axis is the center of the substrate W, and the positions of −150 and 150 on the horizontal axis are opposite ends of the substrate W. In the graph, the vertical axis may represent a relative strength of a magnetic field. For example, the value of 100% on the vertical axis may represent a strength of the magnetic field at the center of the substrate W. For example, each value of the strength of the magnetic field may be measured on or in the vicinity of a top surface of the substrate W. For example, each value of the strength of the magnetic field may be measured at a level below the middle level between a top surface of the chuck 31 and a bottom surface of the plasma window 23. For example, the strengths of the magnetic value may be measured at the same level above the top surface of the chuck 31, e.g. at the same level as the top surface of the substrate W.

In the graph, a first curve C1 shows a distribution of the magnetic field of the plasma PL when the bottom surface 213bs of the core ring 213 is located at the first level LV1. In the graph, a second curve C2 shows a distribution of the magnetic field of the plasma PL when the bottom surface 213bs of the core ring 213 is located at the second level LV2. The strength of the magnetic field on the edge region of the substrate W may be greater when the bottom surface 213bs of the core ring 213 is located at the second level LV2 than when it is located at the first level LV1. For example, as the height or level of the core ring 213 increases, the strength of the magnetic field on the edge region of the substrate W may increase. As a result, an etch rate of the edge region of the substrate W may be increased. For example, as the height or level of the core ring 213 increases, a difference between the strength of the magnetic field on the edge region and on the center region of the substrate W may increase. As a result, etch rate differences between the edge region and the center region of the substrate W may increase.

Referring to FIGS. 6, 8, 10A, 10B, and 10C, the connecting of the rod assembly to at least one of the outer antenna rings (in S25) may include bring at least one of the first outer antenna ring 215a and the first rod 253a into contact with each other, bring the second outer antenna ring 215b and the second rod 253b into contact with each other, and bring the third outer antenna ring 215c and the third rod 253c into contact with each other.

For example, the first rod 253a, the second rod 253b, and the third rod 253c may be placed on the first outer antenna ring 215a, the second outer antenna ring 215b, and the third outer antenna ring 215c, respectively. The first rod 253a, the second rod 253b, and the third rod 253c may include driving devices 259, respectively. The driving devices 259 may be configured to move the first to third rods 253a, 253b, and 253c in a vertical direction. The driving devices 259 may be coupled to the separation plate 25, but the inventive concept is not limited to this example.

Each of the first to third rods 253a, 253b, and 253c may be connected to (e.g., contact) the conductive supporter 255. An RF power, which is generated in the second RF power generator 6, may be supplied to the first to third rods 253a, 253b, and 253c through the conductive supporter 255.

In an embodiment, the first outer antenna ring 215a and the first rod 253a may be in contact with each other. The second outer antenna ring 215b and the second rod 253b may be spaced apart from each other, and the third outer antenna ring 215c and the third rod 253c may be spaced apart from each other. In this case, the RF power of the second RF power generator 6 may be applied to the first outer antenna ring 215a through the first rod 253a. For example, the RF power may be applied to only the first outer antenna ring 215a, and not to the second and third outer antenna rings 215b and 215c.

In an embodiment, the first rod 253a and the first outer antenna ring 215a may be spaced apart from each other by the driving device 259 of the first rod 253a. The third outer antenna ring 215c and the third rod 253c may be in contact with each other by the driving device 259 of the third rod 253c. In this case, the RF power of the second RF power generator 6 may be applied to the third outer antenna ring 215c through the third rod 253c. For example, the RF power may be applied to only the third outer antenna ring 215c, and not to the first and second antenna rings 215a and 215b.

In the graph of FIG. 10C, the horizontal axis may represent center and edge regions of the substrate W, e.g., positions along a horizontal line passing through the center of the substrate W from one edge of the substrate W to an opposite edge of the substrate W. For example, the position of 0 on the horizontal axis is the center of the substrate W, and the positions of −150 and 150 on the horizontal axis are opposite ends of the substrate W. In the graph, the vertical axis may represent a relative strength of a magnetic field. For example, the value of 100% on the vertical axis may represent a strength of the magnetic field at the center of the substrate W.

In the graph, a third curve C3 shows a distribution of the magnetic field of the plasma PL when the first outer antenna ring 215a is in contact with the first rod 253a. In the graph, a fourth curve C4 shows a distribution of the magnetic field of the plasma PL when the third outer antenna ring 215c is in contact with the third rod 253c. The magnetic field may have peaks (e.g., points having the greatest strength of magnetic field) on the edge region of the substrate W. The peaks of the third curve C3 may be closer to the position of 0 on the horizontal axis than the peaks of the fourth curve C4. In the case where the outer antenna ring 215 applied with the RF power is changed/switched from the first outer antenna ring 215a to the third outer antenna ring 215c, the peak of the magnetic field may be moved to a position that is adjacent to the edge region of the substrate W. For example, the position of the peak of the magnetic field may be controlled depending on which of the first to third outer antenna rings 215a, 215b, and 215c the RF power is applied to. Thus, it may be possible to control the etch rate on the edge region of the substrate W.

However, the inventive concept is not limited to this example. For example, the second outer antenna ring 215b and the second rod 253b may be in contact with each other, and in this case, the RF power may be applied to only the second outer antenna ring 215b, and not be applied to the first and third outer antenna rings 215a and 215c. In an embodiment, the RF power may be applied to two of the first to third outer antenna rings 215a, 215b, and 215c. In an embodiment, the RF power may be applied to all of the first to third outer antenna rings 215a, 215b, and 215c. In this way, profiles of the magnetic field formed on the substrate may be controlled and adjusted.

Referring back to FIGS. 6 to 10C, the substrate processing apparatus according to an embodiment of the inventive concept may include the core ring 213 between the inner and outer antenna rings 211 and 215. The height of the core ring 213 may be controlled by the actuators 257. In addition, the core ring 213 may include a magnetic material. The change of the height of the core ring 213 may lead to a change in distribution of the magnetic field on the edge region of the substrate W. Thus, by controlling an etch rate on the edge region of the substrate W, it may be possible to improve the uniformity on the substrate.

According to an embodiment of the inventive concept, the outer antenna ring 215 of the substrate processing apparatus may include the first to third outer antenna rings 215a, 215b, and 215c. The RF power may be applied to at least one of the first to third outer antenna rings 215a, 215b, and 215c with different diameters. Accordingly, a position of a peak of the magnetic field may be controlled. Thus, the uniformity on the substrate W may be improved.

According to an embodiment of the inventive concept, a substrate processing apparatus may include a core ring between an inner antenna ring and an outer antenna ring. A height of the core ring may be controlled by actuators. Thus, the core ring may include a magnetic material. The change of the height of the core ring may lead to a change in distribution of the magnetic field on an edge region of the substrate. Thus, the uniformity on the substrate may be improved.

According to an embodiment of the inventive concept, the outer antenna ring of the substrate processing apparatus may include first to third outer antenna rings. An RF power may be applied to at least one of the first to third outer antenna rings. Accordingly, a position of a peak of the magnetic field may be controlled. Thus, the uniformity on the substrate may be improved.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While example embodiments of the inventive concept have been particularly shown and described, it will be understood by one of ordinary skill in the art that variations in form and detail may be made therein without departing from the spirit and scope of the attached claims.

What is claimed is:

1. A substrate processing apparatus, comprising:
a process chamber; and
a plasma generating portion on the process chamber,
wherein the plasma generating portion comprises:
an inner antenna ring;
a first outer antenna ring surrounding the inner antenna ring; and
a core ring between the inner antenna ring and the first outer antenna ring,
wherein the core ring comprises a magnetic material.

2. The substrate processing apparatus of claim 1, wherein the plasma generating portion further comprises a second outer antenna ring, and a third outer antenna ring, and
the second outer antenna ring is placed between the first outer antenna ring and the third outer antenna ring, when viewed in a plan view.

3. The substrate processing apparatus of claim 2, wherein the first outer antenna ring, the second outer antenna ring, and the third outer antenna ring are horizontally spaced apart from each other.

4. The substrate processing apparatus of claim 2, wherein the plasma generating portion comprises an inner rod connected to the inner antenna ring and an outer rod connected to at least one of the first outer antenna ring, the second outer antenna ring, and the third outer antenna ring.

5. The substrate processing apparatus of claim 1, wherein the core ring is spaced apart from the inner antenna ring and the first outer antenna ring.

6. The substrate processing apparatus of claim 1, wherein the plasma generating portion comprises an actuator connected to the core ring, and
the actuator is configured to control a height of the core ring.

7. The substrate processing apparatus of claim 1, wherein a radius of the core ring ranges from 150 mm to 155 mm.

8. The substrate processing apparatus of claim 1, wherein a height difference between a bottom surface of the core ring and a bottom surface of the first outer antenna ring is less than or equal to 50 mm.

9. A substrate processing apparatus, comprising:
a stage including a cooling plate and a chuck;
a plasma window on the stage;
antenna rings on the plasma window;
a gas supplying device connected to the plasma window; and
an RF power generator electrically connected to the antenna rings,
wherein the antenna rings comprise:
an inner antenna ring; and
first to third outer antenna rings outside the inner antenna ring,
wherein a core ring is placed between the inner antenna ring and the first outer antenna ring and includes a magnetic material.

10. The substrate processing apparatus of claim 9, wherein the second outer antenna ring is placed between the first outer antenna ring and the third outer antenna ring, when viewed in a plan view.

11. The substrate processing apparatus of claim 9, further comprising an actuator placed on and connected to the core ring,
wherein the actuator is configured to control a distance between the core ring and the stage.

12. The substrate processing apparatus of claim 9, further comprising a rod assembly electrically connecting the antenna rings to the RF power generator,
wherein the rod assembly comprises an inner rod, an outer rod, and a conductive supporter electrically connecting the inner rod to the outer rod.

13. The substrate processing apparatus of claim 12, wherein the outer rod comprises a first rod on the first outer antenna ring, a second rod on the second outer antenna ring, and a third rod on the third outer antenna ring.

14. The substrate processing apparatus of claim 9, wherein a diameter of the core ring is larger than or equal to a diameter of the chuck of the stage, when viewed in a plan view.

15. The substrate processing apparatus of claim 9, wherein the RF power generator is configured to supply RF power to the inner antenna ring and at least one of the first to third outer antenna rings.

16. A substrate processing apparatus, comprising:
a process chamber providing a process space;
a stage in the process space of the process chamber;
a plasma window on the process chamber;
an inner antenna ring on the plasma window;
first to third outer antenna rings outside the inner antenna ring and spaced apart from each other;
a core ring between the inner antenna ring and the first outer antenna ring;
an RF power generator electrically connected to the inner antenna ring and at least one of the first to third outer antenna rings; and
an actuator connected to the core ring,
wherein the actuator is configured to move the core ring in a vertical direction.

17. The substrate processing apparatus of claim 16, wherein the core ring comprises a magnetic material, and
a radius of the core ring ranges from 150 mm to 155 mm.

18. The substrate processing apparatus of claim 16, wherein the power generator is configured to form a plasma within the process space of the process chamber.

19. The substrate processing apparatus of claim 16, wherein the core ring is spaced apart from the inner antenna ring and the first to third outer antenna rings.

20. The substrate processing apparatus of claim 16, wherein the inner antenna ring, the first and third outer antenna rings, and the core ring have the same axis of revolution as each other.
